(19) United States
(12) Patent Application Publication
(10) Pub. No.: US 2015/0179555 A1
(43) Pub. Date: Jun. 25, 2015

(54) INTEGRATED CIRCUIT PACKAGING SYSTEM WITH VIALESS SUBSTRATE AND METHOD OF MANUFACTURE THEREOF

(71) Applicants: Sung Soo Kim, Seoul (KR); Byung Tai Do, Singapore (SG); Arnel Senosa Trasporto, Singapore (SG)

(72) Inventors: Sung Soo Kim, Seoul (KR); Byung Tai Do, Singapore (SG); Arnel Senosa Trasporto, Singapore (SG)

(21) Appl. No.: 14/136,513

(22) Filed: Dec. 20, 2013

(51) Int. Cl. H01L 23/495; H01L 21/48

(52) U.S. Cl. CPC H01L 23/49527; H01L 21/4825

(57) ABSTRACT

A system and method of manufacture of an integrated circuit packaging system includes: a trace layer; a stud directly on a portion of the trace layer for forming a metal-to-metal connection with the trace layer; a dielectric layer directly on the trace layer and the stud for forming a vialess substrate exposing the trace layer and the dielectric layer; an active device on the trace layer, the trace layer exposed from the vialess substrate; a die interconnect coupled between the active device to the trace layer for providing electrical connectivity; and an external interconnect connected to the stud for electrically coupling the active device, the trace layer, the studs, and the external interconnect.

### TECHNICAL FIELD

The present invention relates generally to an integrated circuit packaging system, and more particularly to a system with a vialess substrate.

### BACKGROUND ART

Modem electronics, such as smart phones, tablet computers, location based services devices, enterprise class servers, or enterprise class storage arrays, are packing more integrated circuits into an ever-shrinking physical space with expectations for decreasing cost. Numerous technologies have been developed to meet these requirements. Research and development strategies focus on new technologies as well as on improving the existing and mature technologies. Research and development in the existing technologies can take a myriad of different directions.

Modern electronics requirements demand increased functionality in an integrated circuit package while providing less physical space in the system. While these approaches provide more functions within an integrated circuit, they do not fully address the requirements for lower height, smaller space, simplified manufacturing, and cost reduction.

One way to reduce cost is to use mature package technologies with existing manufacturing methods and equipment. The reuse of existing manufacturing processes does not typically result in the reduction of package dimensions. The demand still continues for lower cost, smaller size, improved connectivity, and more functionality.

Thus, a need still remains for an integrated circuit packaging system including lower cost, smaller size, and more functionality. In view of the ever-increasing need to improve integration and cost reduction, it is increasingly critical that answers be found to these problems. Ever-increasing commercial competitive pressures, along with growing consumer expectations, make it critical that answers be found for these problems. Additionally, the need to reduce costs, improve efficiencies and performance, and meet competitive pressures adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: forming a trace layer directly on a base carrier; forming a stud directly on a portion of the trace layer and a portion of the base carrier for forming a metal-to-metal connection with the trace layer; forming a dielectric layer directly on the trace layer, the stud, and the base carrier; forming a vialess substrate by removing the base carrier for exposing the trace layer, the stud, and the dielectric layer; mounting an active device on the trace layer exposed from the vialess substrate, the active device coupled to the trace layer with a die interconnect; and connecting an external interconnect to the stud for electrically coupling the active device, the trace layer, the studs, and the external interconnect.

The present invention provides an integrated circuit packaging system including: a trace layer; a stud directly on a portion of the trace layer for forming a metal-to-metal connection with the trace layer; a dielectric layer directly on the trace layer and the stud for forming a vialess substrate exposing the trace layer and the dielectric layer; an active device on the trace layer, the trace layer exposed from the vialess substrate; a die interconnect coupled between the active device to the trace layer for providing electrical connectivity; and an external interconnect connected to the stud for electrically coupling the active device, the trace layer, the studs, and the external interconnect.

Certain embodiments of the invention have other steps or elements in addition to or in place of those mentioned above. The steps or elements will become apparent to those skilled in the art from a reading of the following detailed description when taken with reference to the accompanying drawings.

### BRIEF DESCRIPTION OF THE DRAWINGS

FIG. 1 is a side view of an integrated circuit packaging system in a first embodiment of the present invention.

FIG. 2 is the structure of FIG. 1 in a provisioning phase of manufacturing.

FIG. 3 is the structure of FIG. 2 in a protecting phase of manufacturing.

FIG. 4 is the structure of FIG. 3 in an opening phase of manufacturing.

FIG. 5 is the structure of FIG. 4 in a removal phase of manufacturing.

FIG. 6 is the structure of FIG. 5 in an attaching phase of manufacturing.

FIG. 7 is the structure of FIG. 6 in an interconnecting phase of manufacturing.

FIG. 8 is the structure of FIG. 7 in a molding phase of manufacturing.

FIG. 9 is the structure of FIG. 8 in a connecting phase of manufacturing.

FIG. 10 is a side view of an integrated circuit packaging system in a second embodiment.

FIG. 11 is a side view of an integrated circuit packaging system in a third embodiment.

FIG. 12 is the structure of FIG. 10 in a provisioning phase of manufacturing.

FIG. 13 is the structure of FIG. 12 in a protecting phase of manufacturing.

FIG. 14 is the structure of FIG. 13 in an opening phase of manufacturing.

FIG. 15 is the structure of FIG. 14 in a removal phase of manufacturing.

FIG. 16 is the structure of FIG. 15 in an attaching phase of manufacturing.

FIG. 17 is the structure of FIG. 16 in a molding phase of manufacturing.

FIG. 18 is the structure of FIG. 17 in a connecting phase of manufacturing.

FIG. 19 is a sideview of an integrated circuit packaging system in a fourth embodiment.

FIG. 20 is the structure of FIG. 19 in a provisioning phase of manufacturing.

FIG. 21 is the structure of FIG. 20 in a protecting phase of manufacturing.

FIG. 22 is the structure of FIG. 21 in an opening phase of manufacturing.

FIG. 23 is the structure of FIG. 22 in a removal phase of manufacturing.

FIG. 24 is the structure of FIG. 23 in an attaching phase of manufacturing.

FIG. 25 is the structure of FIG. 24 in an interconnecting phase of manufacturing.

FIG. 26 is the structure of FIG. 25 in a molding phase of manufacturing.

FIG. 27 is the structure of FIG. 26 in a connecting phase of manufacturing.

FIG. 28 is a flow chart of a method of manufacture of an integrated circuit packaging system in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

Where multiple embodiments are disclosed and described having some features in common, for clarity and ease of illustration, description, and comprehension thereof, similar and like features one to another will ordinarily be described with similar reference numerals. The embodiments have been numbered first embodiment, second embodiment, etc. as a matter of descriptive convenience and are not intended to have any other significance or provide limitations for the present invention.

The term “processing” as used herein includes deposition of material or photoresist, patterning, exposure, development, etching, ablating, grinding, buffing, cleaning, and/or removal of the material or photoresist as required in forming a described structure.

For expository purposes, the term “horizontal” as used herein is defined as a plane parallel to the active side of the integrated circuit, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures.

The term “on” means that there is direct contact between elements. The term “directly on” means that there is direct contact between one element and another element without an intervening element.

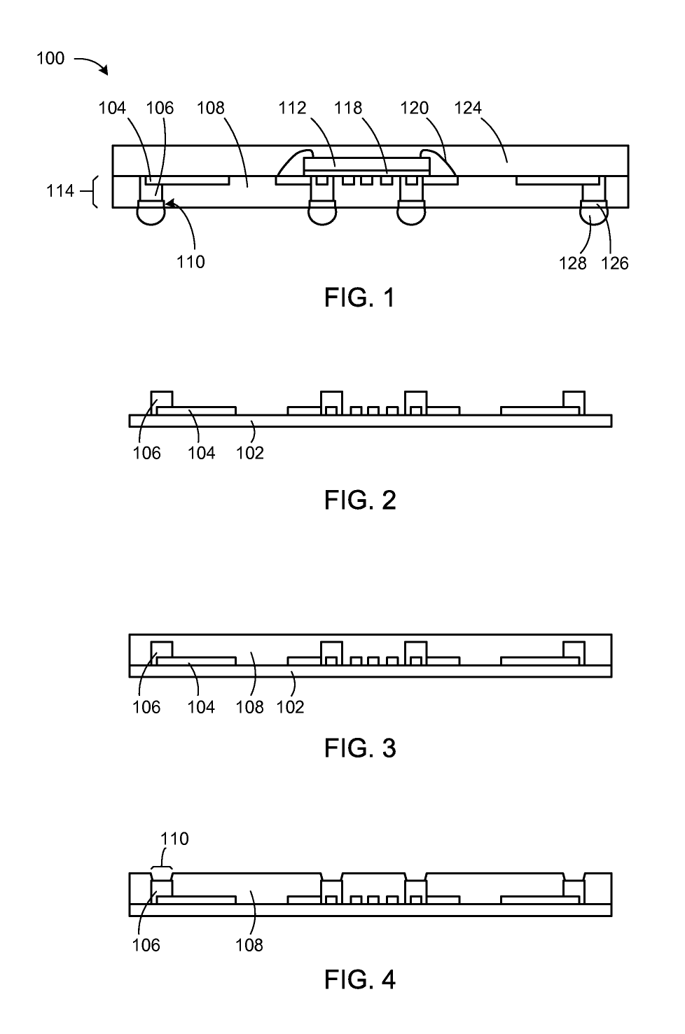

Referring now to FIG. 1, therein is shown a side view of an integrated circuit packaging system 100 in a wirebond embodiment of the present invention. The integrated circuit packaging system 100 can include an active device 112 electrically coupled to a trace layer 104 and studs 106.

The trace layer 104 is an electrically conductive element for distributing signals. The trace layer 104 can be formed from copper, gold, nickel, other metals, metal alloys, other highly conductive materials, or a combination thereof.

The trace layer 104 can include a selective plating (not shown) on bond fingers for connecting to the active device 112, such as a wirebond die. For example, the trace layer 104 can include a protective layer such as an organic solderable preservative (OSP), nickel, gold, or a combination thereof. The trace layer 104 can be configured as a solder-on-pad (SOP) configuration.

The studs 106 are electrically conductive element for conducting signals. The studs 106 can be formed from copper, copper alloy, other metals, metal alloys, other highly conductive metals, or a combination thereof.

The studs 106 can be formed directly on portions of the trace layer 104. The studs 106 can be formed partially on and over the trace layer 104 such that the bottom side of the studs 106 can be coplanar with the bottom side of the trace layer 104. The studs 106 can be offset from the lateral side of the trace layer 104. The studs 106 can form a metal-to-metal connection with the trace layer 104.

In an illustrative example, the studs 106 can be formed over the trace layer 104 using a lithographic process. A mask (not shown) can be formed over the trace layer 104, the material of the studs 106 can be plated over the trace layer 104, and the mask can be removed to leave the studs 106 formed in directly contact with the trace layer 104.

The trace layer 104 can effectively penetrate the studs 106 by forming the studs 106 directly on the trace layer 104. After the trace layer 104 is formed, a lithographic process can be applied over the trace layer 104 to plate the studs 106 directly on the trace layer 104 through openings in lithographic mask (not shown).

The interface between the trace layer 104 and the studs 106 forms a metal-to-metal connection. The interface can have the same composition as the as the bottom copper pads. The studs 106 can completely cover some portions of the trace layer 104 directly under the active device 112. The studs 106 under the active device 112 can provide connectivity to connect to external systems and external connectors.

It has been discovered that forming the studs 106 directly on the trace layer 104 can increase reliability and reduce electrical resistance by creating a solid connection between the studs 106 and the trace layer 104. Improving the quality of the connection between the studs 106 and the trace layer 104 improves signal quality and reduces the thermal footprint of the connection.

The integrated circuit packaging system 100 can include a dielectric layer 108 directly on the studs 106 and the trace layer 104. The dielectric layer 108 is a protective layer. The dielectric layer 108 can be formed from photo sensitive or dielectric material. For example, the dielectric layer 108 can be formed using a dry film solder resist, a film, a liquid, or a combination thereof.

The dielectric layer 108 can hold the studs 106 and the trace layer 104 in place by acting as a structural element and providing mechanical stability. The dielectric layer 108 can electrically isolate and protect the studs 106 and the trace layer 104.

The dielectric layer 108 can include attach pad openings 110 for exposing the studs 106. The attach pad openings 110 can be formed by a lithography process, mechanical ablation, laser ablation, etching, drilling, or a combination thereof.

The attach pad openings 110 can be the same size or larger than the studs 106 to provide access to an entire side of the studs 106. The attach pad openings 110 can extend from a side of the studs 106 facing away from the trace layer 104 to the side of the dielectric layer 108 facing away from the active device 112.

The attach pad openings 110 can have attach pads 126 attached to the side of the studs 106 exposed within the attach pad openings 110. The attach pads 126 are electrically conductive elements for providing attach locations for interconnection elements on the side of the dielectric layer 108 facing away from the trace layer 104. The attach pads 126 can be formed from metal, alloy, solder, conductive material, or a combination thereof. The attach pads 126 can act as structural elements and fill the attach pad openings 110. The attach pads 126 can provide a conductive path to the studs 106.

The attach pads 126 can be connected to external interconnects 128. The external interconnects are electrically conductive elements for connecting to external systems. The external interconnects 128 can be solder balls, solder bumps, solder posts, wires, traces, or a combination thereof.

The integrated circuit packaging system 100 can include the active device 112 mounted over the trace layer 104 and the dielectric layer 108 with an adhesive layer 118. The active device 112 is a microelectronic device. The active device 112 can be a semiconductor, micro-electromechanical device, hybrid device, opto-electric device, or a combination thereof. For example, the active device 112 can be a wirebond die, a flipchip package, a leadless package, a leaded package, a surface mount package, or a combination thereof.

The active device 112 can be electrically coupled to the trace layer 104 with die interconnects 120. The die interconnects 120 are electrically conductive elements for conducting signals to and from the active device 112. For example, the die interconnects 120 can be bond wires, solder balls, traces, leads, connectors, or a combination thereof.

The active device 112 can be attached to the trace layer 104 and the dielectric layer 108 with the adhesive layer 118. The adhesive layer 118 is a structural element for holding the active device 112 in place. For example, the adhesive layer 118 can be formed from an adhesive material such as a polymer, epoxy, resin, or a combination thereof.

The integrated circuit packaging system 100 can include a vialess substrate 114. The vialess substrate 114 is a structural element. The vialess substrate 114 can be used for mounting and supporting the active device 112. The vialess substrate 114 includes the trace layer 104, the dielectric layer 108 with the attach pad openings 110 and the studs 106 exposed on both horizontal sides of the dielectric layer 108. The vialess substrate 114 provides electrical connectivity from one horizontal side to the opposite horizontal side for conducting signals without forming a via in the cured material of the dielectric layer 108.

The integrated circuit packaging system 100 can include an encapsulation 124 formed directly on and over the active device 112, the die interconnects 120, the adhesive layer 118, the studs 106, the trace layer 104, and the dielectric layer 108. The encapsulation 124 is a structural element for protecting the active device 112 and the die interconnects 120.

The encapsulation 124 can be formed from an encapsulation material such as an epoxy, a resin, a polymer, a molding compound, or a combination thereof. The encapsulation 124 can form a hermetic seal around the active device 112 and the die interconnects 120 to keep out dust, moisture, or other environmental contaminants.

It has been discovered that forming the dielectric layer 108 directly on the trace layer 104 and the studs 106 to form a structural element for mounting the active device 112 simplifies manufacturing complexity by eliminating the need for a leadframe. Limiting the number of elements needed to form the integrated circuit packaging system reduces complexity and increases manufacturing throughput.

It has been discovered that forming the dielectric layer 108 directly on and over the trace layer 104 and the studs 106 and forming the attach pad openings 110 to exposed the studs 106 increases functionality and simplifies manufacturing complexity. Forming the dielectric layer 108 directly on and over the studs 106 and forming the attach pad openings 110 can provide an electrical interconnect between the top side and the bottom sides of the dielectric layer 108 without having to drill or mechanically disturb the dielectric layer 108 forming a via completely through the dielectric layer 108.

Referring now to FIG. 2, therein is shown the structure of FIG. 1 in a provisioning phase of manufacturing. The provisioning phase can include a forming method to form the trace layer 104 and the studs 106.

The provisioning phase can include forming a base carrier 102. The base carrier 102 is a temporary structural element where the trace layer 104 and the studs 106 can be formed. The base carrier 102 can be formed with a flexible tape, or with a metal such as an iron alloy, copper, aluminum, or other stiff material that can be removed with an etching solution. The base carrier 102 is formed from a material that can be removed to free the trace layer 104 and the studs 106.

The trace layer 104 can be formed on the base carrier 102. The base carrier can be formed in a variety of ways.

For example, the trace layer 104 can be formed using a lithographic process. A trace layer mask (not shown) can be formed over the base carrier 102 and a layer of trace layer material formed over the trace layer mask and the base carrier 102. The trace layer mask can then be removed leaving the trace layer 104 formed on the base carrier 102.

In another example, the trace layer 104 can be formed by three-dimensional printing. In yet another example, the trace layer 104 can be formed by direct plating, external application of pre-formed traces, or a combination thereof.

The studs 106 can be formed on the trace layer 104 and the base carrier 102. The studs 106 can be formed in a variety of ways.

For example, the studs can be formed using a lithographic process. A stud mask (not shown) can be formed over the trace layer 104 and the base carrier 102 and the material used to form the studs 106 can be formed over the stud mask. The stud mask can include openings having the depth equivalent to the final height of the studs 106 for forming the studs 106.

The stud mask can be removed leaving the studs 106 formed directly on the trace layer 104 and the base carrier 102. The stud mask can be removed in a variety of ways. For example, the stud mask can be removed by etching, chemical solvents, mechanical abrasion, grinding, laser ablation, or a combination thereof.

In another example, the studs 106 can be formed using three dimensional printing to form the studs 106 directly on the trace layer 104. In yet another example, the studs 106 can be formed by direct plating, external application of the studs 106 using pre-formed conductive elements, or a combination thereof.

It has been discovered that forming the studs 106 directly on the trace layer 104 can increase reliability by decreasing the electrical resistance between the studs 106 and the trace layer 104. Plating the material of the studs 106 directly on the trace layer 104 can form a connection with high conductivity.

It has been discovered that forming the trace layer 104 and the studs 106 directly on the base carrier 102 simplifies manufacturing complexity by eliminating the need for a leadframe. Limiting the number of elements needed to form the integrated circuit packaging system can reduce complexity and increase manufacturing throughput.

Referring now to FIG. 3, therein is shown the structure of FIG. 2 in a protecting phase of manufacturing. The protecting phase can include a protecting method to form the dielectric layer 108 directly on the trace layer 104, the studs 106, and the base carrier 102. The dielectric layer 108 covers and protects the trace layer 104 and the studs 106 from external contamination and wear.

The dielectric layer 108 can be formed in a variety of ways. For example, the dielectric layer 108 can be formed by applying a dielectric film over the trace layer 104, the studs 106, and the base carrier 102. The dielectric layer 108 formed with the dielectric film can be conformal to the shape of the trace layer 104, the studs 106, and the base carrier 102.

In another example, a dielectric liquid can be applied directly to the surface of the trace layer 104, the studs 106, and the base carrier 102 to form the dielectric layer 108. The dielectric liquid can include a liquid polymer, epoxy, resin, gel, or a combination thereof. The dielectric liquid can form the dielectric layer 108 shaped using a dielectric layer mold chase (not shown). The dielectric layer 108 formed with the dielectric liquid can be conformal to the shape of the trace layer 104, the studs 106, and the base carrier 102.

Referring now to FIG. 4, therein is shown the structure of FIG. 3 in an opening phase of manufacturing. The opening phase can include an opening method for forming the attach pad openings 110 in the dielectric layer 108 to expose the studs 106.

The attach pad openings 110 can be formed in a variety of ways. For example, the attach pad openings 110 can be formed using a lithographical process to remove material with photosensitive properties. In another example, the attach pad openings 110 can be formed by removing the dielectric material using etching, chemical solvents, mechanical abrasion, grinding, laser ablation, or a combination thereof.

The attach pad openings 110 can be formed in a variety of configurations. For example, the attach pad openings 110 can be the same size as the studs 106 or wider on the surface of the dielectric layer 108 than within the dielectric layer 108. The attach pad openings 110 can be circular, rectangular, triangular, oval, or a combination thereof.

Forming the attach pad openings 110 can leave the characteristics of removal of the dielectric layer 108 on the studs 106. The characteristics of removal of the dielectric layer 108 can include etch marks, scratches, abrasions, residue of the dielectric layer 108, burn marks, thermal damage, or a combination thereof.

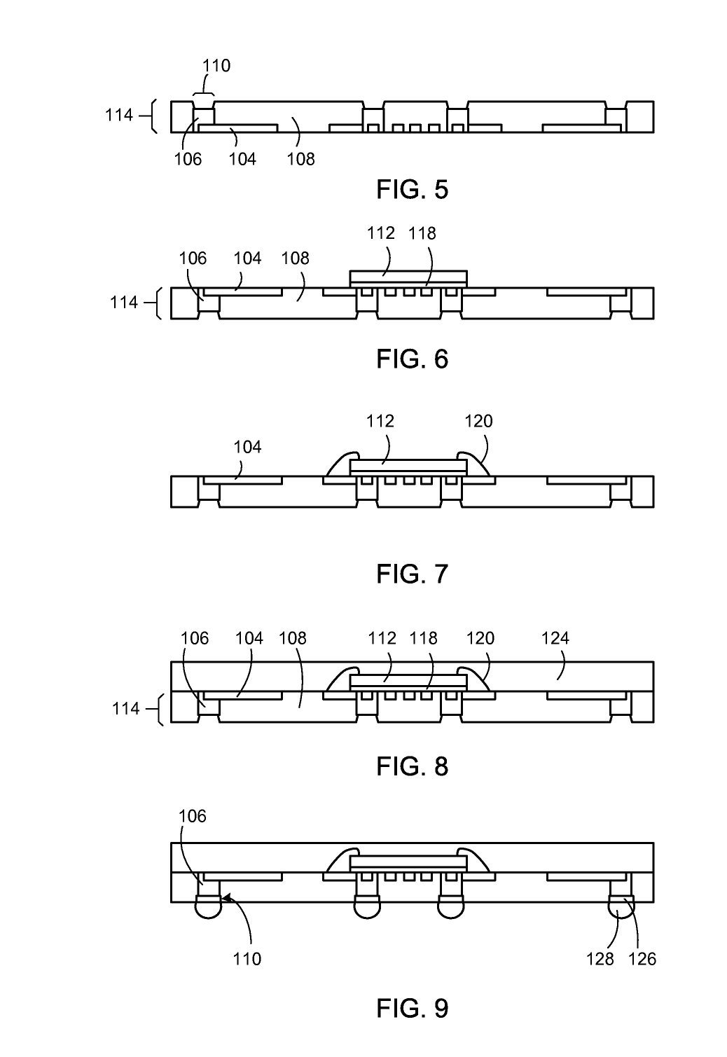

Referring now to FIG. 5, therein is shown the structure of FIG. 4 in a removal phase of manufacturing. The removal phase can include a removal method for removing the base carrier 102 of FIG. 4.

The base carrier 102 can be removed in a variety of ways. For example, the base carrier 102 can be removed by photo-etching, etching, chemical solvents, mechanical abrasion, grinding, laser ablation, or a combination thereof.

Removing the base carrier 102 can leave the characteristics of removal on the sides of the trace layer 104, the studs 106, and the dielectric layer 108 that were covered by the base carrier 102. The characteristics of removal can include etch marks, scratches, abrasions, residue, burn marks, or a combination thereof.

Removing the base carrier 102 forms the vialess substrate 114 having electrical connectivity extending from both horizontal sides. The vialess substrate 114 provides electrical connectivity from one horizontal side to the opposite horizontal side for conducting signals without forming a via in the cured material of the dielectric layer 108.

The studs 106 provide electrical connectivity from one horizontal side of the dielectric layer 108 to the opposite side of the dielectric layer 108 without having to form a via. The studs 106 are exposed and coupled to the trace layer 104 on one side of the vialess substrate 114 and the studs 106 are exposed from the dielectric layer 108 within the attach pad openings 110 on the opposite side of the vialess substrate 114.

Removing the base carrier 102 can expose the trace layer 104, the studs 106, and the dielectric layer 108 all on the trace layer 104 side of the vialess substrate 114. The trace layer 104, the sides of the studs 106, and the side of the dielectric layer 108 all on the trace layer 104 side can be coplanar with one another.

It has been discovered that forming the vialess substrate 114 for mounting the active device 112 simplifies manufacturing complexity by eliminating the need for a leadframe. Limiting the number of elements needed to form the integrated circuit packaging system reduces complexity and increases manufacturing throughput.

Referring now to FIG. 6, therein is shown the structure of FIG. 5 in an attaching phase of manufacturing. The attaching phase can include an attaching method for mounting the active device 112 on and over the trace layer 104, the plugs, and the dielectric layer 108 with the adhesive layer 118.

The active device 112 can be mounted on the substrate by inverting the vialess substrate 114, forming the adhesive layer 118 directly on the vialess substrate 114, and mounting the active device 112 directly on the adhesive layer 118. Inverting the vialess substrate 114 can position the trace layer 104 in an upward facing position to facilitate the mounting of the adhesive layer 118 and the active device 112.

The adhesive layer 118 can be directly on the trace layer 104, the studs 106, and the dielectric layer 108. The adhesive layer 118 can be a polymer, an epoxy, a resin, or a combination thereof. The adhesive layer 118 can be thermally conductive to transfer heat from the active device 112 to the vialess substrate 114.

Referring now to FIG. 7, therein is shown the structure of FIG. 6 in an interconnecting phase of manufacturing. The interconnecting phase can include an interconnecting method for electrically connecting the active device 112 to the trace layer 104 with the die interconnects 120.

The die interconnects 120, such as bond wires, can be electrically connected between the active device 112 and the trace layer 104. Although the die interconnects 120 can be bond wires, it is understood that the die interconnects 120 can be other types of connectors including solder balls, solder bumps, leads, traces, or a combination thereof.

Referring now to FIG. 8, therein is shown the structure of FIG. 7 in a molding phase of manufacturing. The molding phase can include a molding method for forming the encapsulation 124 on and over the vialess substrate 114.

The encapsulation 124 can be formed on the vialess substrate 114 on the side exposing the trace layer 104. The encapsulation 124 can be directly on the active device 112, the die interconnects 120, the adhesive layer 118, the trace layer 104, the studs 106, and the dielectric layer 108.

The encapsulation 124 is a protective structural element. The encapsulation 124 can protect the active device 112, the die interconnects 120, the trace layer 104, the studs 106, and the dielectric layer 108. The encapsulation 124 can be formed from a molding compound, a polymer, an epoxy, a resin, or a combination thereof. The encapsulation 124 can form a hermetic seal to protect the interior elements.

Referring now to FIG. 9, therein is shown the structure of FIG. 8 in a connecting phase of manufacturing. The connecting phase can include a connecting method for connecting the external interconnects 128 to the studs 106.

The external interconnects 128 can be electrically connected to the studs 106 in a variety of ways. For example, the attach pads 126 can be formed directly on the exposed surface of the studs 106 within the attach pad openings 110 and the external interconnects 128 can be formed directly on the attach pads 126. In another example, the external interconnects 128 and the attach pads 126 can be formed directly on the exposed surface of the studs 106 by filling the attach pad openings 110 and extending beyond to form the external interconnects 128 outside the attach pad openings 110.

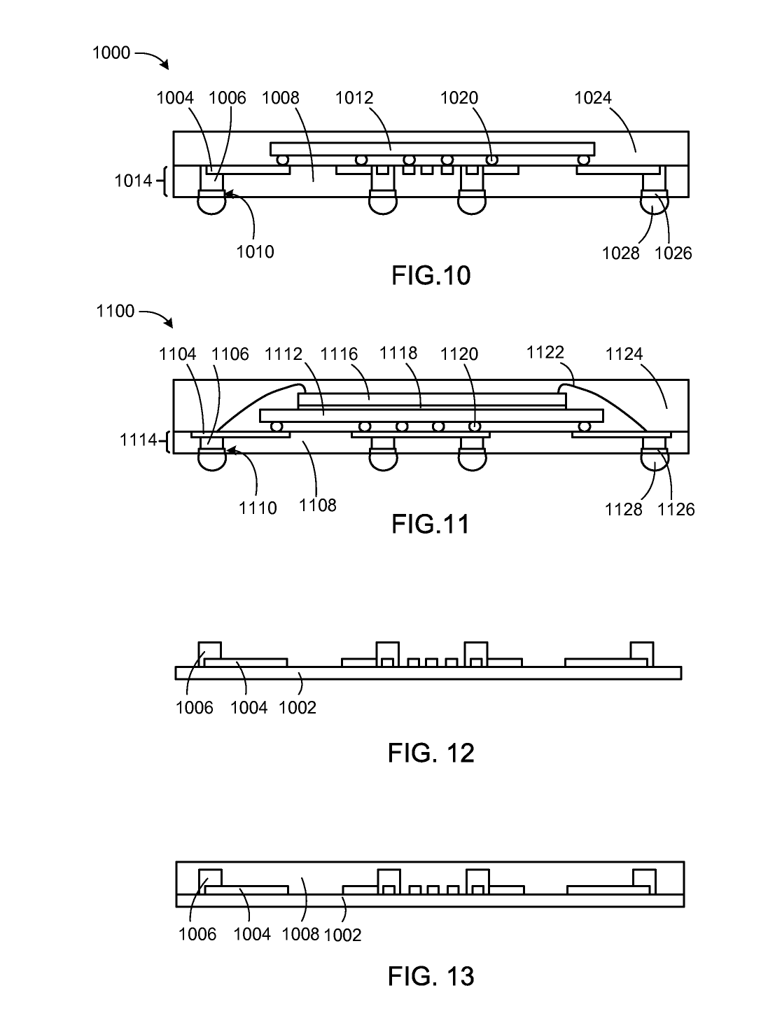

Referring now to FIG. 10, therein is shown a side view of an integrated circuit packaging system 1000 in a second embodiment of the present invention. The integrated circuit packaging system 1000 can include an active device 1012, such as a flipchip, electrically coupled to a trace layer 1004 and studs 1006.

The trace layer 1004 is an electrically conductive element for distributing signals. The trace layer 1004 can be formed from copper, copper alloy, gold, nickel, tin, tin alloy, other metals, metal alloys, other highly conductive materials, or a combination thereof.

The trace layer 1004 can include a selective plating (not shown) on bond fingers for connecting to the active device 1012, such as a wirebond die. For example, the trace layer 1004 can include a protective layer such as an organic solderable preservative (OSP), nickel, gold, or a combination thereof. The trace layer 1004 can be configured as a solder-on-pad (SOP) configuration.

The studs 1006 are electrically conductive elements for conducting signals. The studs 1006 can be formed from copper, copper alloy, other metals, metal alloys, other highly conductive metals, or a combination thereof.

The studs 1006 can be formed directly on portions of the trace layer 1004. The studs 1006 can be formed partially on and over the trace layer 1004 such that the bottom side of the studs 1006 can be coplanar with the bottom side of the trace layer 1004. The studs 1006 can be offset from the lateral side of the trace layer 1004. The studs 1006 can form a metal-to-metal connection with the trace layer 1004.

In an illustrative example, the studs 1006 can be formed over the trace layer 1004 using a lithographic process. A mask (not shown) can be formed over the trace layer 1004, the material of the studs 1006 can be plated over the trace layer 1004, and the mask can be removed to leave the studs 1006 formed in directly contact with the trace layer 1004.

The trace layer 1004 can effectively penetrate the studs 1006 by forming the studs 1006 directly on the trace layer 1004. After the trace layer 1004 is formed, a lithographic process can be applied over the trace layer 1004 to plate the studs 1006 directly on the trace layer 1004 through openings in lithographic mask (not shown).

The interface between the trace layer 1004 and the studs 1006 forms a metal-to-metal connection. The interface can have the same composition as the as the bottom copper pads. The studs 1006 can completely cover some portions of the trace layer 1004 directly under the active device 1012. The studs 1006 under the active device 1012 can provide connectivity to connect to external systems and external connectors.

It has been discovered that forming the studs 1006 directly on the trace layer 1004 can increase reliability and reduce electrical resistance by creating a solid connection between the studs 1006 and the trace layer 1004. Improving the quality of the connection between the studs 1006 and the trace layer 1004 improves signal quality and reduces the thermal footprint of the connection.

The integrated circuit packaging system 1000 can include a dielectric layer 1008 directly on the studs 1006 and the trace layer 1004. The dielectric layer 1008 is a protective layer. The dielectric layer 1008 can be formed from photo sensitive or dielectric material. For example, the dielectric layer 1008 can be formed using a dry film solder resist, a film, a liquid, or a combination thereof.

The dielectric layer 1008 can hold the studs 1006 and the trace layer 1004 in place by acting as a structural element and providing mechanical stability. The dielectric layer 1008 can electrically isolate and protect the studs 1006 and the trace layer 1004.

The dielectric layer 1008 can include attach pad openings 1010 for exposing the studs 1006. The attach pad openings 1010 can be formed by a lithography process, mechanical ablation, laser ablation, etching, drilling, or a combination thereof.

The attach pad openings 1010 can be the same size or larger than the studs 1006 to provide access to an entire side of the studs 1006. The attach pad openings 1010 can extend from a side of the studs 1006 facing away from the trace layer 1004 to the side of the dielectric layer 1008 facing away from the active device 1012.

The attach pad openings 1010 can have attach pads 1026 attached to the side of the studs 1006 exposed within the attach pad openings 1010. The attach pads 1026 are electrically conductive elements for providing attach locations for interconnection elements on the side of the dielectric layer 1008 facing away from the trace layer 1004. The attach pads 1026 can be formed from metal, alloy, solder, conductive material, or a combination thereof. The attach pads 1026 can act as structural elements and fill the attach pad openings 1010. The attach pads 1026 can provide a conductive path to the studs 1006.

The attach pads 1026 can be connected to external interconnects 1028. The external interconnects are electrically conductive elements for connecting to external systems. The external interconnects 1028 can be solder balls, solder bumps, solder posts, wires, traces, or a combination thereof.

The integrated circuit packaging system 1000 can include the active device 1012 mounted over the trace layer 1004 and the dielectric layer 1008. The active device 1012 is a microelectronic device. The active device 1012 can be a semiconductor, micro-electromechanical device, hybrid device, opto-electric device, or a combination thereof. For example, the active device 1012 can be a wirebond die, a flipchip package, a leadless package, a leaded package, a surface mount package, or a combination thereof.

The active device 1012 can be electrically coupled to the trace layer 1004 with die interconnects 1020. The die interconnects 1020 are electrically conductive elements for conducting signals to and from the active device 1012. For example, the die interconnects 1020 can be solder balls, bond wires, traces, leads, connectors, or a combination thereof.

The integrated circuit packaging system 1000 can include a vialess substrate 1014. The vialess substrate 1014 is a structural element. The vialess substrate 1014 can be used for mounting and supporting the active device 1012. The vialess substrate 1014 includes the trace layer 1004, the dielectric layer 1008 with the attach pad openings 1010 and the studs 1006 exposed on both horizontal sides of the dielectric layer 1008. The vialess substrate 1014 provides electrical connectivity from one horizontal side to the opposite horizontal side for conducting signals without forming a via in the cured material of the dielectric layer 1008.

The integrated circuit packaging system 1000 can include an encapsulation 1024 formed directly on and over the active device 1012, the die interconnects 1020, the studs 1006, the trace layer 1004, and the dielectric layer 1008. The encapsulation 1024 is a structural element for protecting the active device 1012 and the die interconnects 1020.

The encapsulation 1024 can be formed from an encapsulation material such as an epoxy, a resin, a polymer, a molding compound, or a combination thereof. The encapsulation 1024 can form a hermetic seal around the active device 1012 and the die interconnects 1020 to keep out dust, moisture, or other environmental contaminants.

It has been discovered that forming the dielectric layer 1008 directly on the trace layer 1004 and the studs 1006 to form a structural element for mounting the active device 1012 simplifies manufacturing complexity by eliminating the need for a leadframe. Limiting the number of elements needed to form the integrated circuit packaging system reduces complexity and increases manufacturing throughput.

It has been discovered that forming the dielectric layer 1008 directly on and over the trace layer 1004 and the studs 1006 and forming the attach pad openings 1010 to exposed the studs 1006 increases functionality and simplifies manufacturing complexity. Forming the dielectric layer 1008 directly on and over the studs 1006 and forming the attach pad openings 1010 can provide an electrical interconnect between the top side and the bottom sides of the dielectric layer 1008 without having to drill or mechanically disturb the dielectric layer 1008 forming a via completely through the dielectric layer 1008.

Referring now to FIG. 11, therein is shown a side view of an integrated circuit packaging system 1100 in a third embodiment of the present invention. The integrated circuit packaging system 1100 can include an active device 1112, such as flipchip or hybrid package, electrically coupled to a trace layer 1104 and studs 1106.

The trace layer 1104 is an electrically conductive element for distributing signals. The trace layer 1104 can be formed from copper, gold, nickel, other metals, metal alloys, other highly conductive materials, or a combination thereof.

The trace layer 1104 can include a selective plating (not shown) on bond fingers for connecting to the active device 1112, such as a wirebond die. For example, the trace layer 1104 can include a protective layer such as an organic solderable preservative (OSP), nickel, gold, or a combination thereof. The trace layer 1104 can be configured as a solder-on-pad (SOP) configuration.

The studs 1106 are electrically conductive element for conducting signals. The studs 1106 can be formed from copper, copper alloy, other metals, metal alloys, other highly conductive metals, or a combination thereof.

The studs 1106 can be formed directly on portions of the trace layer 1104. The studs 1106 can be formed partially on and over the trace layer 1104 such that the bottom side of the studs 1106 can be coplanar with the bottom side of the trace layer 1104. The studs 1106 can be offset from the lateral side of the trace layer 1104. The studs 1106 can form a metal-to-metal connection with the trace layer 1104.

In an illustrative example, the studs 1106 can be formed over the trace layer 1104 using a lithographic process. A mask (not shown) can be formed over the trace layer 1104, the material of the studs 1106 can be plated over the trace layer 1104, and the mask can be removed to leave the studs 1106 formed in directly contact with the trace layer 1104.

The trace layer 1104 can effectively penetrate the studs 1106 by forming the studs 1106 directly on the trace layer 1104. After the trace layer 1104 is formed, a lithographic process can be applied over the trace layer 1104 to plate the studs 1106 directly on the trace layer 1104 through openings in lithographic mask (not shown).

The interface between the trace layer 1104 and the studs 1106 forms a metal-to-metal connection. The interface can have the same composition as the as the bottom copper pads. The studs 1106 can completely cover some portions of the trace layer 1104 directly under the active device 1112. The studs 1106 under the active device 1112 can provide connectivity to connect to external systems and external connectors.

It has been discovered that forming the studs 1106 directly on the trace layer 1104 can increase reliability and reduce electrical resistance by creating a solid connection between the studs 1106 and the trace layer 1104. Improving the quality of the connection between the studs 1106 and the trace layer 1104 improves signal quality and reduces the thermal footprint of the connection.

The integrated circuit packaging system 1100 can include a dielectric layer 1108 directly on the studs 1106 and the trace layer 1104. The dielectric layer 1108 is a protective layer. The dielectric layer 1108 can be formed from photo sensitive or dielectric material. For example, the dielectric layer 1108 can be formed using a dry film solder resist, a film, a liquid, or a combination thereof.

The dielectric layer 1108 can hold the studs 1106 and the trace layer 1104 in place by acting as a structural element and providing mechanical stability. The dielectric layer 1108 can electrically isolate and protect the studs 1106 and the trace layer 1104.

The dielectric layer 1108 can include attach pad openings 1110 for exposing the studs 1106. The attach pad openings 1110 can be formed by a lithography process, mechanical ablation, laser ablation, etching, drilling, or a combination thereof.

The attach pad openings 1110 can be the same size or larger than the studs 1106 to provide access to an entire side of the studs 1106. The attach pad openings 1110 can extend from a side of the studs 1106 facing away from the trace layer 1104 to the side of the dielectric layer 1108 facing away from the active device 1112.

The attach pad openings 1110 can have attach pads 1126 attached to the side of the studs 1106 exposed within the attach pad openings 1110. The attach pads 1126 are electrically conductive elements for providing attach locations for interconnection elements on the side of the dielectric layer 1108 facing away from the trace layer 1104. The attach pads 1126 can be formed from metal, alloy, solder, conductive material, or a combination thereof. The attach pads 1126 can act as structural elements and fill the attach pad openings 1110. The attach pads 1126 can provide a conductive path to the studs 1106.

The attach pads 1126 can be connected to external interconnects 1128. The external interconnects are electrically conductive elements for connecting to external systems. The external interconnects 1128 can be solder balls, solder bumps, solder posts, wires, traces, or a combination thereof.

The integrated circuit packaging system 1100 can include the active device 1112 mounted over the trace layer 1104 and the dielectric layer 1108 with the die interconnects 1120. The active device 1112 is a microelectronic device. The active device 1112 can be a semiconductor, micro-electromechanical device, hybrid device, opto-electric device, or a combination thereof. For example, the active device 1112 can be a wirebond die, a flipchip package, a leadless package, a leaded package, a surface mount package, or a combination thereof.

The active device 1112 can be electrically and physically coupled to the trace layer 1104 with the die interconnects 1120. The die interconnects 1120 are electrically conductive elements for conducting signals between the active device 1112 and the trace layer 1104. For example, the die interconnects 1120 can be solder balls.

The integrated circuit packaging system 1100 can include a secondary device 1116 mounted on the active device 1112 with an adhesive layer 1118. The secondary device 1116 is a microelectronic device. The secondary device 1116 can be a semiconductor, micro-electromechanical device, hybrid device, opto-electric device, or a combination thereof. For example, the secondary device 1116 can be a wirebond die, another flipchip package, a leadless package, a leaded package, a surface mount package, or a combination thereof.

The secondary device 1116 can be electrically connected to the trace layer 1104 with secondary interconnects 1122. The secondary interconnects 1122 are electrical conductors for conducting signals from the secondary device 1116 to the trace layer 1104.

The secondary device 1116 can be attached to the active device 1112 with the adhesive layer 1118. The adhesive layer 1118 can be formed between the active device 1112 and the secondary device 1116. The adhesive layer 1118 is a structural element for bonding the secondary device 1116 to the active device 1112. For example, the adhesive layer 1118 can be an adhesive material such as a polymer, epoxy, resin, or a combination thereof.

The integrated circuit packaging system 1100 can include a vialess substrate 1114. The vialess substrate 1114 is a structural element. The vialess substrate 1114 can be used for mounting and supporting the active device 1112. The vialess substrate 1114 includes the trace layer 1104, the dielectric layer 1108 with the attach pad openings 1110 and the studs 1106 exposed on both horizontal sides of the dielectric layer 1108. The vialess substrate 1114 provides electrical connectivity from one horizontal side to the opposite horizontal side for conducting signals without forming a via in the cured material of the dielectric layer 1108.

The integrated circuit packaging system 1100 can include an encapsulation 1124 formed directly on and over the active device 1112, the die interconnects 1120, the adhesive layer 1118, the studs 1106, the trace layer 1104, and the dielectric layer 1108. The encapsulation 1124 is a structural element for protecting the active device 1112 and the die interconnects 1120.

The encapsulation 1124 can be formed from an encapsulation material such as an epoxy, a resin, a polymer, a molding compound, or a combination thereof. The encapsulation 1124 can form a hermetic seal around the active device 1112 and the die interconnects 1120 to keep out dust, moisture, or other environmental contaminants.

It has been discovered that forming the dielectric layer 1108 directly on the trace layer 1104 and the studs 1106 to form a structural element for mounting the active device 1112 simplifies manufacturing complexity by eliminating the need for a leadframe. Limiting the number of elements needed to form the integrated circuit packaging system reduces complexity and increases manufacturing throughput.

It has been discovered that forming the dielectric layer 1108 directly on and over the trace layer 1104 and the studs 1106 and forming the attach pad openings 1110 to exposed the studs 1106 increases functionality and simplifies manufacturing complexity. Forming the dielectric layer 1108 directly on and over the studs 1106 and forming the attach pad openings 1110 can provide an electrical interconnect between the top side and the bottom sides of the dielectric layer 1108 without having to drill or mechanically disturb the dielectric layer 1108 forming a via completely through the dielectric layer 1108.

Referring now to FIG. 12, therein is shown the structure of FIG. 10 in a provisioning phase of manufacturing. The provisioning phase can include a forming method to form the trace layer 1004 and the studs 1006.

The provisioning phase can include forming a base carrier 1002. The base carrier 1002 is a temporary structural element where the trace layer 1004 and the studs 1006 can be formed. The base carrier 1002 can be formed with a flexible tape, or with a metal such as an iron alloy, copper, aluminum, or other stiff material that can be removed with an etching solution. The base carrier 1002 is formed from a material that can be removed to free the trace layer 1004 and the studs 1006.

The trace layer 1004 can be formed on the base carrier 1002. The base carrier can be formed in a variety of ways.

For example, the trace layer 1004 can be formed using a lithographic process. A trace layer mask (not shown) can be formed over the base carrier 1002 and a layer of trace layer material formed over the trace layer mask and the base carrier 1002. The trace layer mask can then be removed leaving the trace layer 1004 formed on the base carrier 1002.

In another example, the trace layer 1004 can be formed by three-dimensional printing. In yet another example, the trace layer 1004 can be formed by direct plating, external application of pre-formed traces, or a combination thereof.

The studs 1006 can be formed on the trace layer 1004 and the base carrier 1002. The studs 1006 can be formed in a variety of ways.

For example, the studs can be formed using a lithographic process. A stud mask (not shown) can be formed over the trace layer 1004 and the base carrier 1002 and the material used to form the studs 1006 can be formed over the stud mask. The stud mask can include openings having the depth equivalent to the final height of the studs 1006 for forming the studs 1006.

The stud mask can be removed leaving the studs 1006 formed directly on the trace layer 1004 and the base carrier 1002. The stud mask can be removed in a variety of ways. For example, the stud mask can be removed by etching, chemical solvents, mechanical abrasion, grinding, laser ablation, or a combination thereof.

In another example, the studs 1006 can be formed using three dimensional printing to form the studs 1006 directly on the trace layer 1004. In yet another example, the studs 1006 can be formed by direct plating, external application of the studs 1006 using pre-formed conductive elements, or a combination thereof.

It has been discovered that forming the studs 1006 directly on the trace layer 1004 can increase reliability by decreasing the electrical resistance between the studs 1006 and the trace layer 1004. Plating the material of the studs 1006 directly on the trace layer 1004 can form a connection with high conductivity.

It has been discovered that forming the trace layer 1004 and the studs 1006 directly on the base carrier 1002 simplifies manufacturing complexity by eliminating the need for a leadframe. Limiting the number of elements needed to form the integrated circuit packaging system can reduce complexity and increase manufacturing throughput.

Referring now to FIG. 13, therein is shown the structure of FIG. 12 in a protecting phase of manufacturing. The protecting phase can include a protecting method to form the dielectric layer 1008 directly on the trace layer 1004, the studs 1006, and the base carrier 1002. The dielectric layer 1008 covers and protects the trace layer 1004 and the studs 1006 from external contamination and wear.

The dielectric layer 1008 can be formed in a variety of ways. For example, the dielectric layer 1008 can be formed by applying a dielectric film over the trace layer 1004, the studs 1006, and the base carrier 1002. The dielectric layer 1008 formed with the dielectric film can be conformal to the shape of the trace layer 1004, the studs 1006, and the base carrier 1002.

In another example, a dielectric liquid can be applied directly to the surface of the trace layer 1004, the studs 1006, and the base carrier 1002 to form the dielectric layer 1008. The dielectric liquid can include a liquid polymer, epoxy, resin, gel, or a combination thereof. The dielectric liquid can form the dielectric layer 1008 shaped using a dielectric layer mold chase (not shown). The dielectric layer 1008 formed with the dielectric liquid can be conformal to the shape of the trace layer 1004, the studs 1006, and the base carrier 1002.

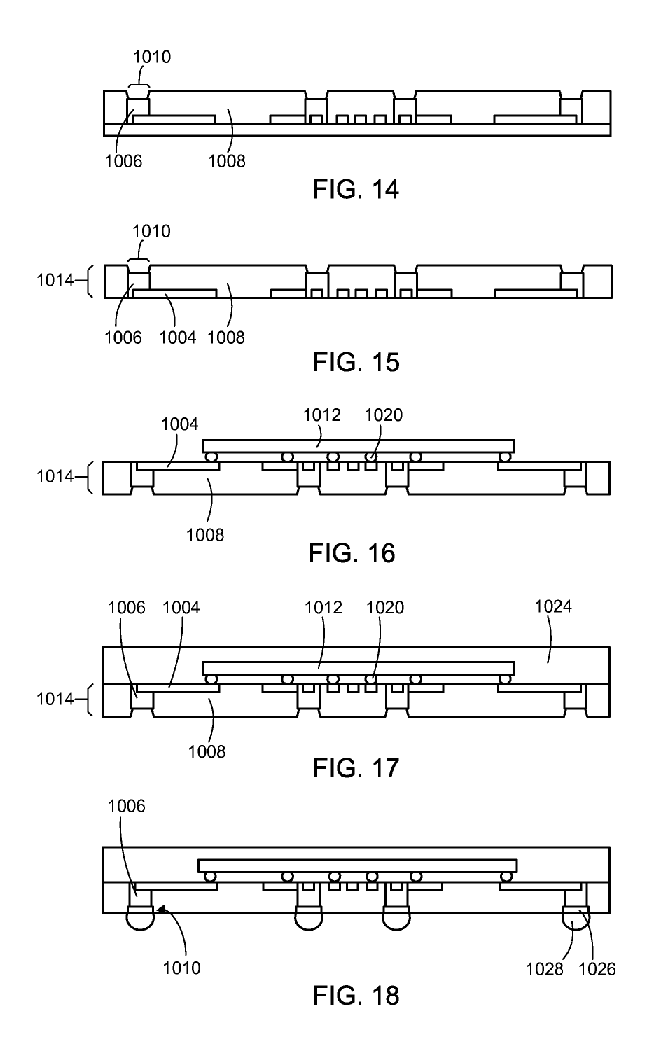

Referring now to FIG. 14, therein is shown the structure of FIG. 13 in an opening phase of manufacturing. The opening phase can include an opening method for forming the attach pad openings 1010 in the dielectric layer 1008 to expose the studs 1006.

The attach pad openings 1010 can be formed in a variety of ways. For example, the attach pad openings 1010 can be formed using a lithographical process to remove material with photosensitive properties. In another example, the attach pad openings 1010 can be formed by removing the dielectric material using etching, chemical solvents, mechanical abrasion, grinding, laser ablation, or a combination thereof.

The attach pad openings 1010 can be formed in a variety of configurations. For example, the attach pad openings 1010 can be the same size as the studs 1006 or wider on the surface of the dielectric layer 1008 than within the dielectric layer 1008. The attach pad openings 1010 can be circular, rectangular, triangular, oval, or a combination thereof.

Forming the attach pad openings 1010 can leave the characteristics of removal of the dielectric layer 1008 on the studs 1006. The characteristics of removal of the dielectric layer 1008 can include etch marks, scratches, abrasions, residue of the dielectric layer 1008, burn marks, thermal damage, or a combination thereof.

Referring now to FIG. 15, therein is shown the structure of FIG. 14 in a removal phase of manufacturing. The removal phase can include a removal method for removing the base carrier 1002 of FIG. 14.

The base carrier 1002 can be removed in a variety of ways. For example, the base carrier 1002 can be removed by photo-etching, etching, chemical solvents, mechanical abrasion, grinding, laser ablation, or a combination thereof.

Removing the base carrier 1002 can leave the characteristics of removal on the sides of the trace layer 1004, the studs 1006, and the dielectric layer 1008 that were covered by the base carrier 1002. The characteristics of removal can include etch marks, scratches, abrasions, residue, burn marks, or a combination thereof.

Removing the base carrier 1002 forms a vialess substrate 1014 having electrical connectivity extending from both horizontal sides. The vialess substrate 1014 provides electrical connectivity from one horizontal side to the opposite horizontal side for conducting signals without forming a via in the cured dielectric layer 1008.

The studs 1006 provide electrical connectivity from one horizontal side of the dielectric layer 1008 to the opposite side of the dielectric layer 1008 without having to form a via. The studs 1006 are exposed and coupled to the trace layer 1004 on one side of the vialess substrate 1014 and the studs 1006 are exposed from the dielectric layer 1008 within the attach pad openings 1010 on the opposite side of the vialess substrate 1014.

Removing the base carrier 1002 can expose the trace layer 1004, the studs 1006, and the dielectric layer 1008 all on the trace layer 1004 side of the vialess substrate 1014. The trace layer 1004, the sides of the studs 1006, and the side of the dielectric layer 1008 all on the trace layer 1004 side can be coplanar with one another.

It has been discovered that forming the vialess substrate 1014 for mounting the active device 1012 simplifies manufacturing complexity by eliminating the need for a leadframe. Limiting the number of elements needed to form the integrated circuit packaging system reduces complexity and increases manufacturing throughput.

Referring now to FIG. 16, therein is shown the structure of FIG. 15 in an attaching phase of manufacturing. The attaching phase can include an attaching method for mounting the active device 1012 on and over the trace layer 1004, the plugs, and the dielectric layer 1008 with the die interconnects 1020.

The active device 1012 can be mounted on the substrate by inverting the vialess substrate 1014, forming the die interconnects 1020 directly on the vialess substrate 1014, and mounting the active device 1012 directly on the die interconnects 1020. Inverting the vialess substrate 1014 can position the trace layer 1004 in an upward facing position to facilitate the mounting of the die interconnects 1020 and the active device 1012.

The active device 1012 can be electrically connected to the trace layer 1004 with the die interconnects 1020. The die interconnects 1020, such as solder balls, can be electrically connected between the active device 1012 and the trace layer 1004. The die interconnects 1020 can be thermally conductive to transfer heat from the active device 1012 to the vialess substrate 1014.

Referring now to FIG. 17, therein is shown the structure of FIG. 16 in a molding phase of manufacturing. The molding phase can include a molding method for forming the encapsulation 1024 on and over the vialess substrate 1014.

The encapsulation 1024 can be formed on the vialess substrate 1014 on the side exposing the trace layer 1004. The encapsulation 1024 can be directly on the active device 1012, the die interconnects 1020, the trace layer 1004, the studs 1006, and the dielectric layer 1008.

The encapsulation 1024 is a protective structural element. The encapsulation 1024 can protect the active device 1012, the die interconnects 1020, the trace layer 1004, the studs 1006, and the dielectric layer 1008. The encapsulation 1024 can be formed from a molding compound, a polymer, an epoxy, a resin, or a combination thereof. The encapsulation 1024 can form a hermetic seal to protect the interior elements.

Referring now to FIG. 18, therein is shown the structure of FIG. 17 in a connecting phase of manufacturing. The connecting phase can include a connecting method for connecting the external interconnects 1028 to the studs 1006.

The external interconnects 1028 can be electrically connected to the studs 1006 in a variety of ways. For example, the attach pads 1026 can be formed directly on the exposed surface of the studs 1006 within the attach pad openings 1010 and the external interconnects 1028 can be formed directly on the attach pads 1026. In another example, the external interconnects 1028 and the attach pads 1026 can be formed directly on the exposed surface of the studs 1006 by filling the attach pad openings 1010 and extending beyond to form the external interconnects 1028 outside the attach pad openings 1010.

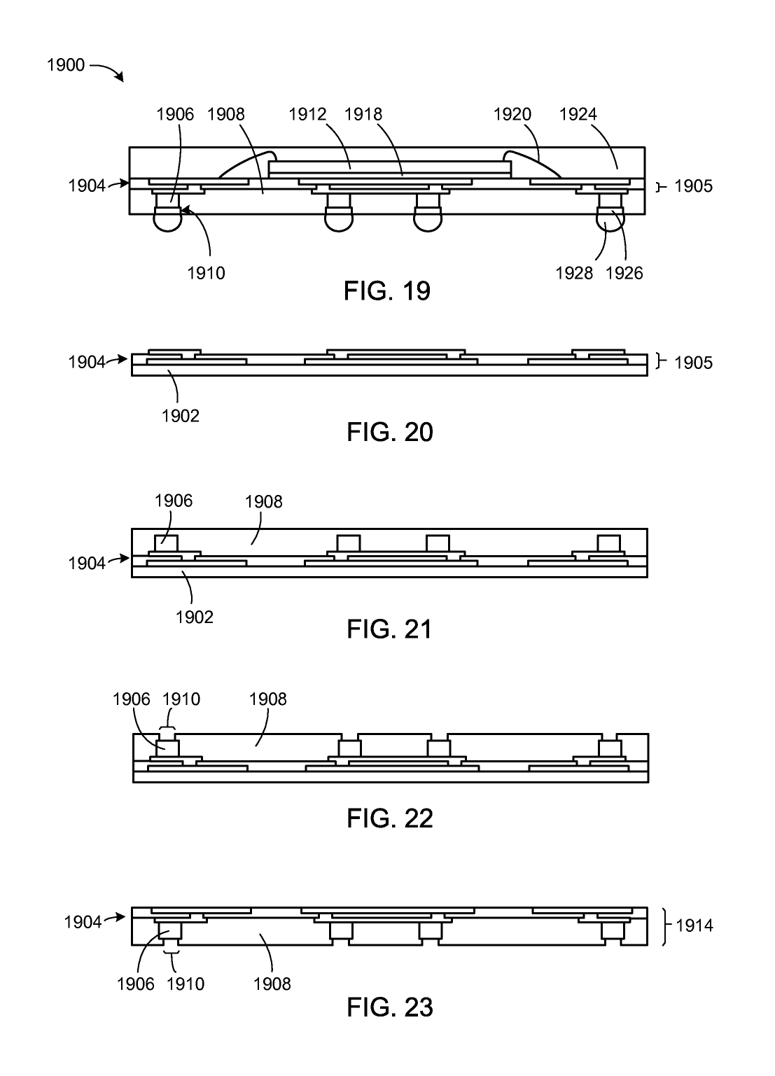

Referring now to FIG. 19, therein is shown a side view of an integrated circuit packaging system 1900 in a fourth embodiment of the present invention. The integrated circuit packaging system 1900 can include an active device 1912, such as a wire bond die, electrically coupled to a trace layer 1904 and studs 1906.

The trace layer 1904 is an electrically conductive element for distributing signals. The trace layer 1904 can be formed from copper, gold, nickel, other metals, metal alloys, other highly conductive materials, or a combination thereof. The trace layer 1904 can include a plurality of layers. For example, the trace layer 1904 can include multiple of the redistribution layers 1905 for directing electrical signals with the redistribution layers 1905 electrically connected to one another.

The trace layer 1904 can include a selective plating (not shown) on bond fingers for connecting to the active device 1912, such as a wirebond die. For example, the trace layer 1904 can include a protective layer such as an organic solderable preservative (OSP), nickel, gold, or a combination thereof. The trace layer 1904 can be configured as a solder-on-pad (SOP) configuration.

The studs 1906 are electrically conductive elements for conducting signals. The studs 1906 can be formed from copper, copper alloy, other metals, metal alloys, other highly conductive metals, or a combination thereof.

The studs 1906 can be formed directly on a portion of the trace layer 1904. The studs 1906 can be formed partially on and over the trace layer 1904 such that the bottom side of the studs 1906 can be coplanar with the bottom side of the trace layer 1904. The studs 1906 can be offset from the lateral side of the trace layer 1904. The studs 1906 can form a metal-to-metal connection with the trace layer 1904.

In an illustrative example, the studs 1906 can be formed over the trace layer 1904 using a lithographic process. A mask (not shown) can be formed over the trace layer 1904, the material of the studs 1906 can be plated over the trace layer 1904, and the mask can be removed to leave the studs 1906 formed in directly contact with the trace layer 1904.

The trace layer 1904 can effectively penetrate the studs 1906 by forming the studs 1906 directly on the trace layer 1904. After the trace layer 1904 is formed, a lithographic process can be applied over the trace layer 1904 to plate the studs 1906 directly on the trace layer 1904 through openings in lithographic mask (not shown).

The interface between the trace layer 1904 and the studs 1906 forms a metal-to-metal connection. The interface can have the same composition as the as the bottom copper pads. The studs 1906 can completely cover some portions of the trace layer 1904 directly under the active device 1912. The studs 1906 under the active device 1912 can provide connectivity to connect to external systems and external connectors.

It has been discovered that forming the studs 1906 directly on the trace layer 1904 can increase reliability and reduce electrical resistance by creating a solid connection between the studs 1906 and the trace layer 1904. Improving the quality of the connection between the studs 1906 and the trace layer 1904 improves signal quality and reduces the thermal footprint of the connection.

The integrated circuit packaging system 1900 can include a dielectric layer 1908 directly on the studs 1906 and the trace layer 1904. The dielectric layer 1908 is a protective layer. The dielectric layer 1908 can be formed from photo sensitive or dielectric material. For example, the dielectric layer 1908 can be formed using a dry film solder resist, a film, a liquid, or a combination thereof.

The dielectric layer 1908 can hold the studs 1906 and the trace layer 1904 in place by acting as a structural element and providing mechanical stability. The dielectric layer 1908 can electrically isolate and protect the studs 1906 and the trace layer 1904.

The dielectric layer 1908 can include attach pad openings 1910 for exposing the studs 1906. The attach pad openings 1910 can be formed by a lithography process, mechanical ablation, laser ablation, etching, drilling, or a combination thereof.

The attach pad openings 1910 can be the same size or larger than the studs 1906 to provide access to an entire side of the studs 1906. The attach pad openings 1910 can extend from a side of the studs 1906 facing away from the trace layer 1904 to the side of the dielectric layer 1908 facing away from the active device 1912.

The attach pad openings 1910 can have attach pads 1926 attached to the side of the studs 1906 exposed within the attach pad openings 1910. The attach pads 1926 are electrically conductive elements for providing attach locations for interconnection elements. The attach pads 1926 can be formed from metal, alloy, solder, conductive material, or a combination thereof. The attach pads 1926 can act as structural elements and fill the attach pad openings 1910. The attach pads 1926 can provide a conductive path to the studs 1906.

The attach pads 1926 can be connected to external interconnects 1928. The external interconnects are electrically conductive elements for connecting to external systems. The external interconnects 1928 can be solder balls, solder bumps, solder posts, wires, traces, or a combination thereof.

The integrated circuit packaging system 1900 can include the active device 1912 mounted over the trace layer 1904 and the dielectric layer 1908 with the adhesive layer 1918. The active device 1912 is a microelectronic device. The active device 1912 can be a semiconductor, micro-electromechanical device, hybrid device, opto-electric device, or a combination thereof. For example, the active device 1912 can be a wirebond die, a flipchip package, a leadless package, a leaded package, a surface mount package, or a combination thereof.

The active device 1912 can be electrically coupled to the trace layer 1904 with die interconnects 1920. The die interconnects 1920 are electrically conductive elements for conducting signals to and from the active device 1912. For example, the die interconnects 1920 can be bond wires, solder balls, traces, leads, connectors, or a combination thereof.

The active device 1912 can be attached to the trace layer 1904 and the dielectric layer 1908 with the adhesive layer 1918. The adhesive layer 1918 is a structural element for holding the active device 1912 in place. For example, the adhesive layer 1918 can be formed from an adhesive material such as a polymer, epoxy, resin, or a combination thereof.

The integrated circuit packaging system 1900 can include a vialess substrate 1914. The vialess substrate 1914 is a structural element. The vialess substrate 1914 can be used for mounting and supporting the active device 1912. The vialess substrate 1914 includes the trace layer 1904, the dielectric layer 1908 with the attach pad openings 1910 and the studs 1906 exposed on both horizontal sides of the dielectric layer 1908. The vialess substrate 1914 provides electrical connectivity from one horizontal side to the opposite horizontal side for conducting signals without forming a via in the cured material of the dielectric layer 1908.

The integrated circuit packaging system 1900 can include an encapsulation 1924 formed directly on and over the active device 1912, the die interconnects 1920, the adhesive layer 1918, the trace layer 1904, and the dielectric layer 1908. The encapsulation 1924 is a structural element for protecting the active device 1912 and the die interconnects 1920.

The encapsulation 1924 can be formed from an encapsulation material such as an epoxy, a resin, a polymer, a molding compound, or a combination thereof. The encapsulation 1924 can form a hermetic seal around the active device 1912 and the die interconnects 1920 to keep out dust, moisture, or other environmental contaminants.

It has been discovered that forming the dielectric layer 1908 directly on the trace layer 1904 and the studs 1906 to form a structural element for mounting the active device 1912 simplifies manufacturing complexity by eliminating the need for a leadframe. Limiting the number of elements needed to form the integrated circuit packaging system reduces complexity and increases manufacturing throughput.

It has been discovered that forming the dielectric layer 1908 directly on and over the trace layer 1904 and the studs 1906 and forming the attach pad openings 1910 to exposed the studs 1906 increases functionality and simplifies manufacturing complexity. Forming the dielectric layer 1908 directly on and over the studs 1906 and forming the attach pad openings 1910 can provide an electrical interconnect between the top side and the bottom sides of the dielectric layer 1908 without having to drill or mechanically disturb the dielectric layer 1908 forming a via completely through the dielectric layer 1908.

Referring now to FIG. 20, therein is shown the structure of FIG. 19 in a provisioning phase of manufacturing. The provisioning phase can include a forming method to form the trace layer 1904.

The provisioning phase can include forming a base carrier 1902. The base carrier 1902 is a temporary structural element where the trace layer 1904 can be formed. The base carrier 1902 can be formed with a flexible tape, or with a metal such as an iron alloy, copper, aluminum, or other stiff material that can be removed with an etching solution. The base carrier 1902 is formed from a material that can be removed to free the trace layer 1904.

The trace layer 1904 can be formed on the base carrier 1902. The base carrier can be formed in a variety of ways. The trace layer 1904 can include two or more of the redistribution layers 1905 separate by a dielectric material. The redistribution layers 1905 can be vertically interconnected by vertical opening formed by mechanical, laser, or lithographic techniques including etching, chemical solvents, mechanical abrasion, grinding, laser ablation, or a combination thereof. The trace layer 1904 can include a bottom side protective layer formed from photosensitive material.

For example, the trace layer 1904 can be formed using a lithographic process. One or more trace layer mask (not shown) can be formed over the base carrier 1902 and one or more layers of the trace layer material and the dielectric material can be formed over the base carrier 1902. The trace layer mask can then be removed leaving the trace layer 1904 formed on the base carrier 1902.

In another example, the trace layer 1904 can be formed by three-dimensional printing. In yet another example, the trace layer 1904 can be formed by direct plating, external application of pre-formed traces, or a combination thereof.

Referring now to FIG. 21, therein is shown the structure of FIG. 20 in a protecting phase of manufacturing. The protecting phase can include a protecting method to form the studs 1906 and then the dielectric layer 1908 directly on the trace layer 1904, the studs 1906, and the base carrier 1902. The dielectric layer 1908 covers and protects the trace layer 1904 and the studs 1906 from external contamination and wear.

The studs 1906 can be formed on the trace layer 1904. The studs 1906 can be formed in a variety of ways.

For example, the studs can be formed using a lithographic process. A stud mask (not shown) can be formed over the trace layer 1904 and the base carrier 1902 and the material used to form the studs 1906 can be formed over the stud mask. The stud mask can include openings having the depth equivalent to the final height of the studs 1906 for forming the studs 1906.

The stud mask can be removed leaving the studs 1906 formed directly on the trace layer 1904. The stud mask can be removed in a variety of ways. For example, the stud mask can be removed by etching, chemical solvents, mechanical abrasion, grinding, laser ablation, or a combination thereof.

In another example, the studs 1906 can be formed using three dimensional printing to form the studs 1906 directly on the trace layer 1904. In yet another example, the studs 1906 can be formed by direct plating, external application of the studs 1906 using pre-formed conductive elements, or a combination thereof.

It has been discovered that forming the studs 1906 directly on the trace layer 1904 can increase reliability by decreasing the electrical resistance between the studs 1906 and the trace layer 1904. Plating the material of the studs 1906 directly on the trace layer 1904 can form a connection with high conductivity.

Once the studs 1906 have been formed on the trace layer 1904, the dielectric layer 1908 can be formed over the trace layer 1904 and the studs 1906. The dielectric layer 1908 can be formed in a variety of ways. For example, the dielectric layer 1908 can be formed by applying a dielectric film over the trace layer 1904 and the studs 1906. The dielectric layer 1908 formed with the dielectric film can be conformal to the shape of the trace layer 1904 and the studs 1906.

In another example, a dielectric liquid can be applied directly to the surface of the trace layer 1904 and the studs 1906 to form the dielectric layer 1908. The dielectric liquid can include a liquid polymer, epoxy, resin, gel, or a combination thereof. The dielectric liquid can form the dielectric layer 1908 shaped using a dielectric layer mold chase (not shown). The dielectric layer 1908 formed with the dielectric liquid can be conformal to the shape of the trace layer 1904 and the studs 1906.

Referring now to FIG. 22, therein is shown the structure of FIG. 21 in an opening phase of manufacturing. The opening phase can include an opening method for forming the attach pad openings 1910 in the dielectric layer 1908 to expose the studs 1906.

The attach pad openings 1910 can be formed in a variety of ways. For example, the attach pad openings 1910 can be formed using a lithographical process to remove material with photosensitive properties. In another example, the attach pad openings 1910 can be formed by removing portions of the dielectric layer 1908 using etching, chemical solvents, mechanical abrasion, grinding, laser ablation, or a combination thereof.

The attach pad openings 1910 can be formed in a variety of configurations. For example, the attach pad openings 1910 can be the same size as the studs 1906 or wider on the surface of the dielectric layer 1908 than within the dielectric layer 1908. The attach pad openings 1910 can be circular, rectangular, triangular, oval, or a combination thereof.

Forming the attach pad openings 1910 can leave the characteristics of removal of the dielectric layer 1908 on the studs 1906. The characteristics of removal of the dielectric layer 1908 can include etch marks, scratches, abrasions, residue of the dielectric layer 1908, burn marks, thermal damage, or a combination thereof.

Referring now to FIG. 23, therein is shown the structure of FIG. 22 in a removal phase of manufacturing. The removal phase can include a removal method for removing the base carrier 1902 of FIG. 22.

The base carrier 1902 can be removed in a variety of ways. For example, the base carrier 1902 can be removed by photo-etching, etching, chemical solvents, mechanical abrasion, grinding, laser ablation, or a combination thereof.

Removing the base carrier 1902 can leave the characteristics of removal on the sides of the trace layer 1904 covered by the base carrier 1902. The characteristics of removal can include etch marks, scratches, abrasions, residue, burn marks, or a combination thereof.

Removing the base carrier 1902 forms a vialess substrate 1914 having electrical connectivity extending from both horizontal sides. The vialess substrate 1914 provides electrical connectivity from one horizontal side to the opposite horizontal side for conducting signals without forming a via in the cured dielectric layer 1908.

The studs 1906 and the trace layer 1904 can provide electrical connectivity from one horizontal side of the dielectric layer 1908 to the opposite side of the dielectric layer 1908 without having to form a via. The studs 1906 are exposed and coupled to the trace layer 1904 on one side of the vialess substrate 1914 and the studs 1906 are exposed from the dielectric layer 1908 within the attach pad openings 1910 on the opposite side of the vialess substrate 1914. Removing the base carrier 1902 can expose the trace layer 1904.

It has been discovered that forming the vialess substrate 1914 for mounting the active device 1912 simplifies manufacturing complexity by eliminating the need for a leadframe. Limiting the number of elements needed to form the integrated circuit packaging system reduces complexity and increases manufacturing throughput.

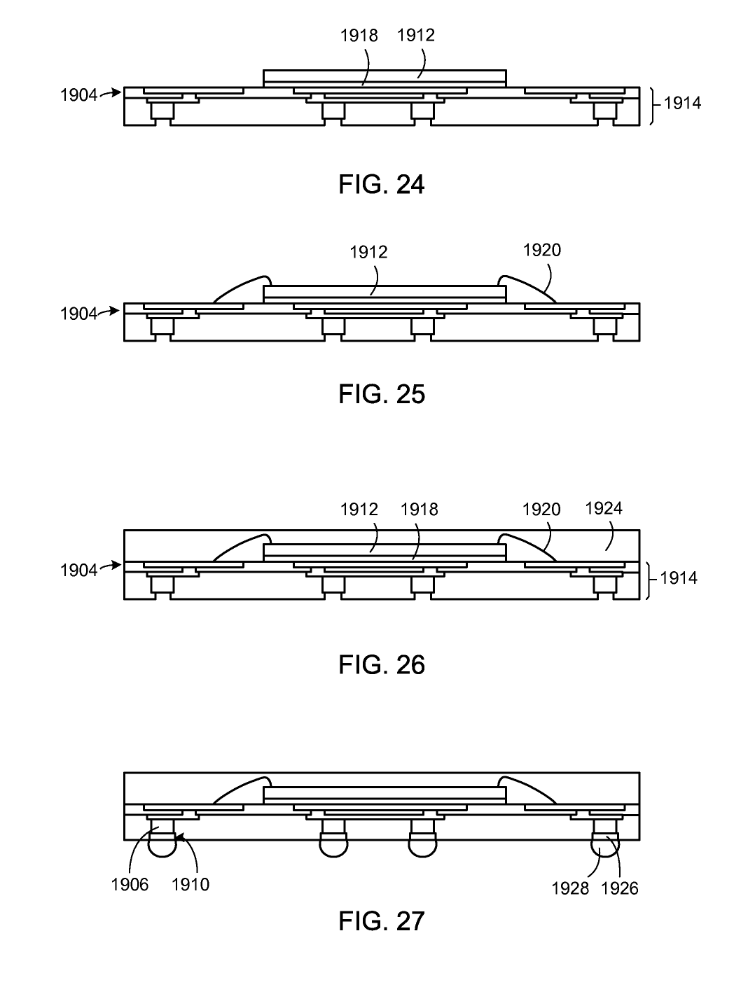

Referring now to FIG. 24, therein is shown the structure of FIG. 23 in an attaching phase of manufacturing. The attaching phase can include an attaching method for mounting the active device 1912 on and over the trace layer 1904 with the adhesive layer 1918.

The active device 1912 can be mounted on the substrate by inverting the vialess substrate 1914, forming the adhesive layer 1918 directly on the vialess substrate 1914, and mounting the active device 1912 directly on the adhesive layer 1918. Inverting the vialess substrate 1914 can position the trace layer 1904 in an upward facing position to facilitate the forming of the adhesive layer 1918 and mounting of the active device 1912. For example, the active device 1912 can be a wire bond die.

The adhesive layer 1918 can be directly on the trace layer 1904 of the vialess substrate 1914. The adhesive layer 1918 can be a polymer, an epoxy, a resin, or a combination thereof. The adhesive layer 1918 can be thermally conductive to transfer heat from the active device 1912 to the vialess substrate 1914.

Referring now to FIG. 25, therein is shown the structure of FIG. 24 in an interconnecting phase of manufacturing. The interconnecting phase can include an interconnecting method for electrically connecting the active device 1912 to the trace layer 1904 with the die interconnects 1920.

The die interconnects 1920, such as bond wires, can be electrically connected between the active device 1912 and the trace layer 1904. Although the die interconnects 1920 can be bond wires, it is understood that the die interconnects 1920 can be other types of connectors including solder balls, solder bumps, leads, traces, or a combination thereof.

Referring now to FIG. 26, therein is shown the structure of FIG. 24 in a molding phase of manufacturing. The molding phase can include a molding method for forming the encapsulation 1924 on and over the vialess substrate 1914.

The encapsulation 1924 can be formed on the vialess substrate 1914 on the side exposing the trace layer 1904. The encapsulation 1924 can be directly on the active device 1912, the die interconnects 1920, the adhesive layer 1918, and the trace layer 1904.

The encapsulation 1924 is a protective structural element. The encapsulation 1924 can protect the active device 1912, the die interconnects 1920, and the trace layer 1904 from contaminants and wear. The encapsulation 1924 can be formed from a molding compound, a polymer, an epoxy, a resin, or a combination thereof. The encapsulation 1924 can form a hermetic seal to protect the interior elements.

Referring now to FIG. 27, therein is shown the structure of FIG. 26 in a connecting phase of manufacturing. The connecting phase can include a connecting method for connecting the external interconnects 1928 to the studs 1906.

The external interconnects 1928 can be electrically connected to the studs 1906 in a variety of ways. For example, the attach pads 1926 can be formed directly on the exposed surface of the studs 1906 within the attach pad openings 1910 and the external interconnects 1928 can be formed directly on the attach pads 1926. In another example, the external interconnects 1928 and the attach pads 1926 can be formed directly on the exposed surface of the studs 1906 by filling the attach pad openings 1910 and extending beyond to form the external interconnects 1928 outside the attach pad openings 1910.

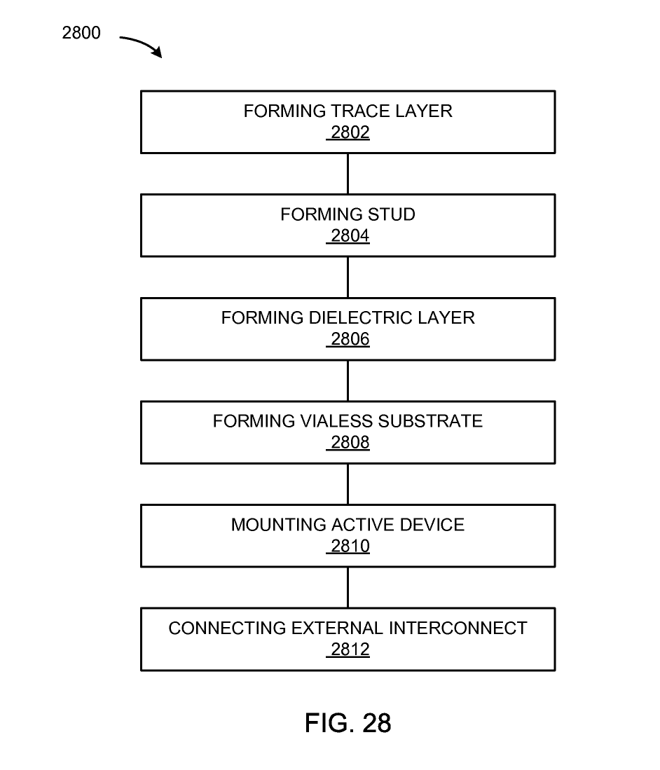

Referring now to FIG. 28, therein is shown a flow chart of a method 2800 of manufacture of an integrated circuit packaging system in a further embodiment of the present invention. The method 2800 includes: forming a trace layer directly on a base carrier in a block 2802; forming a stud directly on a portion of the trace layer and a portion of the base carrier for forming a metal-to-metal connection with the trace layer in a block 2804; forming a dielectric layer directly on the trace layer, the stud, and the base carrier in a block 2806; forming a vialess substrate by removing the base carrier for exposing the trace layer, the stud, and the dielectric layer in a block 2808; mounting an active device on the trace layer exposed from the vialess substrate, the active device coupled to the trace layer with a die interconnect in a block 2810; and connecting an external interconnect to the stud for electrically coupling the active device, the trace layer, the studs, and the external interconnect in a block 2812.

Thus, it has been discovered that the integrated circuit packaging system of the present invention furnishes important and heretofore unknown and unavailable solutions, capabilities, and functional aspects for an integrated circuit packaging system. The resulting method, process, apparatus, device, product, and/or system is straightforward, cost-effective, uncomplicated, highly versatile and effective, can be surprisingly and unobviously implemented by adapting known technologies, and are thus readily suited for efficiently and economically manufacturing integrated circuit packaging systems fully compatible with conventional manufacturing methods or processes and technologies.

Another important aspect of the present invention is that it valuably supports and services the historical trend of reducing costs, simplifying manufacturing, and increasing performance. These and other valuable aspects of the present invention consequently further the state of the technology to at least the next level.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacture of an integrated circuit packaging system comprising:
forming a trace layer directly on a base carrier;
forming a stud directly on a portion of the trace layer and a portion of the base carrier for forming a metal-to-metal connection with the trace layer;
forming a dielectric layer directly on the trace layer, the stud, and the base carrier;
forming a vialess substrate by removing the base carrier for exposing the trace layer, the stud, and the dielectric layer;
mounting an active device on the trace layer exposed from the vialess substrate, the active device coupled to the trace layer with a die interconnect; and
connecting an external interconnect to the stud for electrically coupling the active device, the trace layer, the studs, and the external interconnect.

2. The method as claimed in claim 1 further comprising forming an attach pad opening in the dielectric layer for exposing the stud.

3. The method as claimed in claim 1 wherein connecting the external interconnect includes forming an attach pad directly on the stud and within the attach pad opening for attaching the external interconnect.

4. The method as claimed in claim 1 wherein forming the trace layer includes forming the trace layer having a plurality of redistribution layers.

5. The method as claimed in claim 1 wherein mounting the active device includes attaching a bond wire between the trace layer and a wire bond die.

6. A method of manufacture of an integrated circuit packaging system comprising:
forming a trace layer directly on a base carrier;
forming a stud directly on a portion of the trace layer and a portion of the base carrier for forming a metal-to-metal connection with the trace layer;
forming a dielectric layer directly on the trace layer, the stud, and the base carrier;
forming a vialess substrate by removing the base carrier for exposing the trace layer, the stud, and the dielectric layer;
mounting an active device on the trace layer exposed from the vialess substrate, the active device attached to the trace layer with a solder ball;
forming an encapsulation directly on and over the active device, the die interconnect, and the trace layer of the vialess substrate;
forming an attach pad opening in the dielectric layer for exposing the stud; and
connecting an external interconnect to the stud for electrically coupling the active device, the trace layer, the studs, and the external interconnect.

7. The method as claimed in claim 6 wherein forming the attach pad opening includes etching the attach pad opening.

8. The method as claimed in claim 6 wherein connecting the external interconnect includes forming the attach pad and the external interconnect together.

9. The method as claimed in claim 6 wherein forming the trace layer includes forming the trace layer having a plurality of redistribution layers.

10. The method as claimed in claim 6 wherein mounting the active device includes mounting a secondary device on the active device with an adhesive layer, the secondary device coupled to the trace layer with a secondary interconnect.

11. An integrated circuit packaging system comprising:
a trace layer;
a stud directly on a portion of the trace layer for forming a metal-to-metal connection with the trace layer;
a dielectric layer directly on the trace layer and the stud for forming a vialess substrate exposing the trace layer and the dielectric layer;
an active device on the trace layer, the trace layer exposed from the vialess substrate;
a die interconnect coupled between the active device to the trace layer for providing electrical connectivity; and
an external interconnect connected to the stud for electrically coupling the active device, the trace layer, the studs, and the external interconnect.

12. The system as claimed in claim 11 further comprising an attach pad opening in the dielectric layer for exposing the stud.

13. The system as claimed in claim 11 further comprising:
an attach pad opening in the dielectric layer for exposing the stud; and
an attach pad directly on the stud and within the attach pad opening for attaching the external interconnect.

14. The system as claimed in claim 11 wherein the trace layer includes a plurality of redistribution layers.

15. The system as claimed in claim 11 wherein the die interconnect is a bond wire between the trace layer and the active device.

16. The system as claimed in claim 11 further comprising:
a solder ball for attaching the active device to the trace layer;
an encapsulation directly on and over the active device, the die interconnect, and the trace layer of the vialess substrate; and
an attach pad opening in the dielectric layer for exposing the stud.

17. The system as claimed in claim 16 wherein the stud within the attach pad opening has the characteristics of removal of the dielectric layer.

18. The system as claimed in claim 16 further comprising an attach pad directly on the external interconnect.

19. The system as claimed in claim 16 wherein the trace layer includes a plurality of redistribution layers.

20. The system as claimed in claim 16 further comprising:
a secondary device attached to the active device with an adhesive layer; and
a secondary interconnect between the secondary device and the trace layer for electrically coupling the secondary device and the trace layer.
